(19) United States
(12) Patent Application Publication
(10) Pub. No.: US 2006/0138626 A1
(43) Pub. Date: Jun. 29, 2006

(54) Microelectronic packages using a ceramic substrate having a window and a conductive surface region

(75) Inventors: Victor Liew, Fremont, CA (US); Giles Humpston, San Jose, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/025,432

(22) Filed: Dec. 29, 2004

(51) Int. Cl. H01L 23/06

(52) U.S. Cl. 257/684

(57) ABSTRACT

A microelectronic package includes a microelectronic device, a unitary ceramic substrate, and a plurality of terminals. The microelectronic device has a front surface and a plurality of electrical contacts thereon. The substrate has first and second opposing surfaces. A window extends from a first opening on the first surface along a side wall to a second opening on the second surface. A conductive region may be provided on the side wall and/or the second substrate surface. The substrate is located between the device and the terminals such that the first surface of the substrate faces the front surface of the device and the first opening is aligned with at least one contact on the front device surface. Also provided are methods for producing microelectronic packages and wafer-scale assemblies.

### BACKGROUND OF THE INVENTION

The invention relates generally to microelectronic packages. In particular, the invention relates to microelectronic packages that employ a ceramic substrate having a conductive surface region, optionally on a window side wall, to which a microelectronic device may be electrically connected. Also provided are wafer-scale microelectronic assemblies and methods for forming microelectronic packages and assemblies.

Microelectronic devices such as semiconductor chips are often packaged with a substrate to provide a convenient vehicle for mounting and electrically connecting the device. For example, semiconductor chips typically are flat bodies with contacts disposed on the front surface that are connected to the internal electrical circuitry of the chip itself. Semiconductor chips are typically packaged with substrates to form microelectronic packages having terminals that are electrically connected to the chip contacts. The package may then be connected to test equipment to determine whether the packaged device conforms to a desired performance standard. Once tested, the package may be connected to a larger circuit, e.g., a circuit in an electronic product such as a computer or a cell phone.

In general, substrate materials are selected for their compatible with the processes used to form the package. For example, during solder or other bonding operations, intense heat may be applied to the substrate. Accordingly, metal lead frames have been used as substrates. Laminate substrates have also been used to package microelectronic devices. Such substrates may include two to four alternating layers fiberglass and epoxy, wherein successive fiberglass layers may be laid in traversing, e.g., orthogonal, directions. Optionally, heat resistive compounds such as bismaleimide triazine (BT) may be added to such laminate substrates.

Tapes have been used as substrates to provide thinner microelectronic packages. Such tapes are typically provided in the form of sheets or rolls of sheets. For example, single and double sided sheets of copper-on-polyimide are commonly used for fine-line and high-density electronic interconnection applications. Polyimide base films offer good thermal and chemical stability and a low dielectric constant, while copper having high tensile strength, ductility, and flexure have been advantageously used in both flexible circuit and chip scale packaging applications. However, such tapes are relatively expensive, particularly as compared to lead frames and laminate substrates.

Depending on the configuration and other requirements of the microelectronic package, different substrate materials may be used. For example, in a flip-chip configuration, the front or contact-bearing surface of the microelectronic device faces towards a substrate. Each contact on the device is joined by a solder bond to a corresponding contact pad on the substrate, by positioning solder balls on the substrate or device, juxtaposing the device with the substrate, and momentarily reflowing the solder. The flip-chip configuration, however, encounters problems in thermal expansion mismatch. When the coefficient of thermal expansion (CTE) for the device differs significantly from the CTE for the substrate, the solder connections will undergo fatigue when the package is thermally cycled. This is particularly problematic for flip-chip packages with fine pitch, small bumps, and/or large device footprints. Thus, to enhance reliability, the substrate is typically selected such that its CTE closely matches the CTE of the device.

To improve productivity and reduce costs associated with microelectronic manufacturing, it has been proposed that microelectronic packages be formed as a wafer-scale assembly. Wafer-scale assemblies allow a plurality of devices in the form of a wafer to be packaged with a substrate as a single structure. Once formed, the wafer-scale structure is diced and separated into individual packages. However, problems associated with CTE mismatch between the wafer and the substrate are exacerbated due to the size of the wafer-scale structure. Thus, wafer-scale manufacturing of microelectronic packages may require exceptionally close matching of device and substrate CTE.

For semiconductor-based optical devices, both ceramic and semiconductor materials have been proposed for use as substrate materials, though semiconductor materials are, as a rule, significantly more expensive than ceramic materials. For example, U.S. Pat. No. 6,429,511 to Ruby et al. describes a wafer package that includes base and cap wafers comprised of the same material, e.g., silicon, sealed to define a hermetically sealed volume between the wafers. In addition, a number of patents describe technologies relating to an integrally packaged optronic circuit device that includes an integrated circuit and an insulating cover plate of comprises glass, quartz, sapphire or another radiation transparent insulative substrate. See, e.g., U.S. Pat. Nos. 5,455,455, 5,547,906, 6,040,235, 6,117,707, and 6,646,289. In some instances, microelectronic devices may be packaged with glass covers having tapered through holes. See, e.g., U.S. patent application Ser. No. 10/949,674, filed Sep. 24, 2004, entitled “STRUCTURE AND METHOD OF MAKING CAPPED CHIPS HAVING VERTICAL INTERCONNECTS.”

U.S. Pat. No. 6,753,208 to MacIntyre describes a chip scale package structure formed by adhering a glass sheet having a pattern of holes matching a pattern of bond pads on a semiconductor wafer so that the pattern of holes on the glass sheet are over the pattern of bond pads on the semiconductor wafer. Metallized pads are formed on the glass sheet adjacent to each hole. A conductive trace may be formed from each metallized pad on the glass sheet to the bond pad on the semiconductor wafer under the adjacent hole. In addition, the pad may extend down the sides of the adjacent hole, which may then be filled with a metal plug that electrically connects the pad on the glass sheet to the bond pad on the semiconductor wafer.

Nevertheless, there exist further opportunities in the art to provide alternatives and improved technologies for microelectronic packages, particularly those technologies that lend themselves to wafer-scale manufacturing of low profile, high-performance packages.

### SUMMARY OF THE INVENTION

In one aspect, the invention provides a microelectronic package that includes a microelectronic device, a unitary ceramic substrate, and a plurality of terminals. The microelectronic device has a substantially planar front surface and a plurality of electrical contacts thereon. The substrate has a first substantially planar surface and a second surface opposing first surface. A window extends from a first opening on the first surface along a side wall to a second opening on the second surface. A conductive region may be provided on the side wall and/or the second substrate surface. Typically, but not necessarily, the window has varied cross-sectional areas along its lumen as defined by its side wall. The substrate is located between the device and the terminals such that the first surface of the substrate faces the front surface of the device and the first opening is aligned with at least one contact on the front device surface.

The microelectronic device may be take any number of forms including, but not limited to, a memory chip. Often, the electrical contacts of the device are located in a central portion of the front device surface, e.g., along a device bisecting line. In some instances, the contacts are substantially absent from a peripheral portion of the front device surface.

Any of a number of ceramic materials may be used to form the substrate. Typically, the substrate is comprised of an amorphous ceramic material. In addition, the substrate may have any number of shapes and/or geometry. For example, the second substrate surface may be substantially planar and/or be substantially parallel to the first substrate surface. In some instances, one or more recesses may be present in the second substrate surface.

Similarly, any window extending through the substrate may be of a number of geometries and/or shapes. For example, the first opening may have a smaller cross-sectional area than the second opening. In such a case, the side wall may be tapered from the second opening to the first opening. In addition or in the alternative, the side wall may include a ledge. The conductive region may be present on the ledge. Optionally, the first and second openings may both be aligned with the electrical contacts on the front surface of the device.

In general, the terminals are typically located on the second substrate surface. When present on the second substrate surface, a recess may contain one or more terminals. Optionally, solder and solder resist may lie on the second surface of the substrate.

In any case, the terminal and the conductive region may be comprised of a contiguous coating of substantially uniform composition. Typically, a metal is used to form a coating that has a thickness of no greater than about 5 micrometers. In some instances, contiguous coating may be no more than about 3 micrometers thick. To achieve a thickness of about 0.1 to about 1 micrometer, sputtering, evaporation, and other vapor deposition techniques may be used.

The device and the substrate may be coupled or decoupled to each other. However, there is typically substantially no void between the first surface of the substrate and the front surface of the device. For example, an adhesive may be provided between the device and the substrate. In addition, the package may include a compliant layer between the device and at least one terminal, e.g., between the at least one terminal and the substrate and/or between the device and the substrate. Accordingly, one or more terminals and the substrate may be coupled or decoupled to each other.

The device contacts electrically communicate with the terminals in any of a number of ways. For example, one or more device contacts may be provided in electrical communication with at least one terminal through the window via one ore more conductive regions. This may be achieved by lead bonding or wire bonding the contacts to the conductive region. Once electrical communication is achieved, an encapsulant may be dispensed into the window, optionally filling the window to a substantially void-free degree.

A further aspect of the invention provides a wafer-scale microelectronic assembly that includes a wafer and a unitary ceramic substrate. The wafer includes an array of microelectronic devices each having a coplanar front surface and a plurality of electrical contacts thereon. The ceramic substrate has a first substantially planar surface and a second surface opposing first surface. One or more windows extend from a first opening on the first surface along a side wall to a second opening on the second surface. The windows may or may not have varied cross-sectional areas. One ore more conductive regions are located on at least one side wall or the second surface. The first surface of the substrate faces the front device surfaces, and each first opening is aligned with at least one electrical contact, typically on different devices. When the wafer has a diameter of at least 200 mm, the substrate and the device may have coefficients of thermal expansion that differs by no more than about 0.1 ppm/°C.

Yet another aspect of the invention provides a method for forming a microelectronic package. The method involves using a microelectronic device similar or identical to those described above and a unitary ceramic substrate similar or identical to those described above. The device and the substrate are arranged such that the first substrate surface faces the front device surface and the first opening is aligned with at least one contact on the front device surface. Once the device and the substrate are aligned with each other, electrical communication is established between at least one contact and the conductive region through the first opening, optionally through lead bonding or wire bonding. Further optionally, the window may be filled with an encapsulant.

A further aspect of the invention provides a method for forming a microelectronic assembly by using a wafer that includes an array of microelectronic device instead of a single device or a plurality of devices that are not arranged in an array. Once completed, the assembly may be diced to form individual microelectronic packages.

### BRIEF DESCRIPTION OF THE DRAWINGS

FIG. 1 schematically illustrates in cross-sectional view an exemplary package of the invention that includes a substrate having a window through which contacts on a chip are wire or lead bonded to terminals.

FIGS. 2A-2C, collectively referred to as FIG. 2, schematically depicts the front surface of various microelectronic devices, each having at least one array of contacts in a central portion of its front surface. FIG. 2A depicts a microelectronic device having a linear array of contacts. FIG. 2B depicts a microelectronic device having a rectilinear array of contacts. FIG. 2C depicts a microelectronic device having colinear arrays of contacts.

FIGS. 3A and 3B, collectively referred to as FIG. 3, schematically illustrate an exemplary package of the invention using a substrate having a window that has side wall ledge. FIG. 3A depicts the package plan view. FIG. 3B depicts the package in cross-sectional view.

FIGS. 4A and 4B, collectively referred to as FIG. 4, schematically illustrate an exemplary package of the invention that includes a substrate having a window with a tapered side wall. FIG. 4A depicts the package in plan view. FIG. 4B depicts an interconnect portion of the package in cross-sectional view.

FIG. 5 schematically illustrates in cross-sectional view an interconnect structure for an exemplary package similar to that depicted in FIG. 4 except that the second surface of the substrate includes a recess containing a solder ball.

FIG. 6 schematically illustrates in cross-sectional view an interconnect structure for an exemplary package similar to that depicted in FIG. 4 except that the package includes a cavity between the device and the substrate.

FIG. 7 schematically illustrates in cross-sectional view an interconnect structure for an exemplary package similar to that depicted in FIG. 4 except that the package includes a compliant layer.

### DETAILED DESCRIPTION

It is to be understood that the invention is not limited to specific microelectronic devices or types of electronic products, as such may vary. It is also to be understood that the terminology used herein is for the purpose of describing particular embodiments only, and is not intended to be limiting.

As used in this specification and the appended claims, the singular article forms “a,” “an,” and “the”include both singular and plural referents unless the context clearly dictates otherwise. Thus, for example, reference to “a conductive region,” includes a plurality of conductive regions as well as a single conductive region, reference to “a microelectronic device” includes a single device as well as a combination of devices, and the like.

In addition, terminology indicative or suggestive of a particular spatial relationship between elements of the invention is to be construed in a relative sense rather an absolute sense unless the context of usage clearly dictates to the contrary. For example, the term “face-down” as used to describe the spatial orientation of the device does not necessarily indicate that the front surface of the device represents the lowest point of the device. In addition, a “substrate” is not necessarily located below another element, e.g., a microelectronic device, of the microelectronic package. Thus, in a package that includes a substrate and device in a face-down orientation, the substrate may be located above, at the same level, or below the front device surface depending on the package's orientation.

Certain embodiments of the invention provide a microelectronic package that includes for a microelectronic device, a plurality of terminals, and an interposing substrate therebetween. The microelectronic device has a substantially planar front surface and a plurality of electrical contacts thereon. The substrate has a first substantially planar surface and a second surface opposing first surface. Notably, the substrate is formed at least in part from a ceramic material. As used herein, the term “ceramic” is used in its ordinary sense and generally refers to a hard, brittle, heat-resistant and corrosion-resistant dielectric material made typically made by heating an inorganic compound, e.g., single or mixed metal oxides such as aluminum, zirconium or silicon oxides, nitrides, and carbides, at a high temperature. A ceramic material may be single crystalline, multicrystalline, or, as in the case of glass, amorphous.

In any case, a window extends from a first opening on the first substrate surface along a side wall to a second opening on the second substrate surface. The terminals may be in direct or indirect contact with the second substrate surface. Regardless the terminals contact or is spaced apart from the substrate, the terminals may be coupled or decoupled from the substrate. Optionally, In any case, the device contacts may be electrical connected to the terminals through the window.

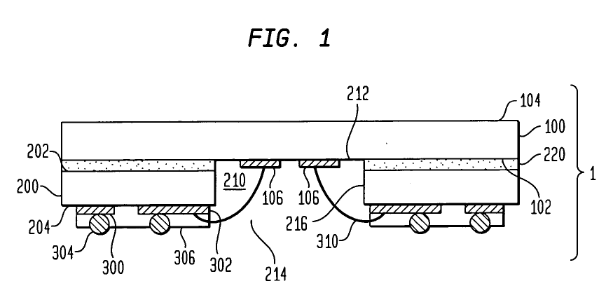

FIG. 1 depicts an exemplary package according to one embodiment of the invention. As with all figures referenced herein, in which like parts are referenced by like numerals, FIG. 1 is not to scale, and certain dimensions may be exaggerated for clarity of presentation. As shown, package 1 includes a microelectronic device 100. The microelectronic device 100 is generally depicted as having opposing front and rear major surfaces indicated at 102 and 104, respectively. The front and rear surfaces are depicted as substantially planar and parallel to each other. The front surface 102 of the microelectronic device 100 includes a plurality of electrical contacts 106.

The microelectronic devices of the invention may take any of a number of forms, including, but not limited to, the form of a chip or a wafer. While the device typically has opposing front and rear surfaces, wherein the front surface provides electrical accessibility, microelectronic devices of any geometry may benefit from the invention. In addition, the invention may be used in conjunction with microelectronic devices used for any of a number of applications, including, for example, semiconductor processors, memory chips, microelectromechanical systems (MEMS), optical devices, and microfluidic devices. Furthermore, the device may be constructed to contain or exclude specific feature according to the intended use of the device. For example, when the device is not intended for optical applications, the device may contain no optically sensitive and/or emitting element.

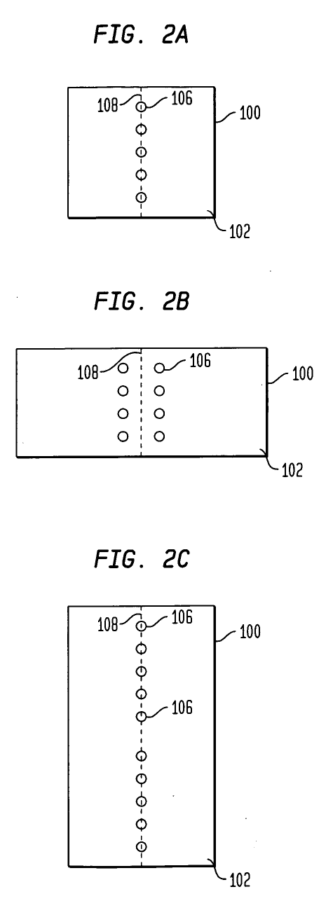

Typically, the electrical contacts on the front surface of the microelectronic are arranged in an ordered arrangement, i.e., an array such as rectilinear grids, parallel stripes, spirals, and the like. For example, FIG. 2 schematically illustrates various microelectronic devices 100 each having at least one array of contacts 106 on its front surface 102. FIG. 2A depicts a microelectronic device 100 having a square front surface 102. A linear array of contacts 106, i.e., a plurality of colinear contacts having equidistant neighboring contacts, lies along a dotted line 108 defined by center points of opposing edges of the device that bisects the front surface 102. As another example, FIG. 2B depicts a microelectronic device 100 having a rectangular front surface 102. A rectilinear array of contacts 106 are arranged on the front surface 102 in parallel columns. The columns exhibit mirror symmetry along a dotted line 108 that bisects surface 102 in a widthwise manner. As yet another example, FIG. 2C depicts a microelectronic device 100 having rectangular front surface 102. Two linear arrays of contacts 106 are arranged on the front surface 102 lies along the same dotted line 108 that bisects surface 102 along in a lengthwise manner. Thus, as shown in FIG. 2, the electrical contacts of the device are generally located in a central portion of the front device surface, optionally in a manner such that they are substantially absent from a peripheral portion of the device surface.

Turning again to FIG. 1, the substrate includes opposing first and second surfaces, indicated at 202 and 204, respectively, that are each substantially planar and parallel to each other. A window 210 is extends from a first opening 212 on the first substrate surface 202 through the substrate 210 to a second opening 214 on the second substrate surface 204. As shown, the first and second openings 212 and 214 are substantially identical in size, and the window 210 has a substantially constant cross-sectional area through its length. Thus, opposing portions of side wall 216 are depicted as parallel to each other. Optionally, the substrate 200 may have a footprint that is substantially identical to that of the device 100.

The thickness of the substrate and the size of the openings may vary. For example, the substrate typically has a thickness comparable to the thickness of the device. However, the thicknesses may, on occasion differ by as much as an order of magnitude. In any case, the substrate thickness is typically less than about 1 millimeter. Substrates having a thickness of about 100 to about 300 micrometers are often used to package devices of comparable thickness. For such packages, the window openings may have diameters on the order of 70 to 300 μm.

As shown in FIG. 1, the device 100 is placed face-down on the substrate 200 such that the front device surface 102 faces the first substrate surface 202, and the device contacts 106 are aligned with the window 210. Optionally, both the first and second openings 212, 214 of the window 210 are aligned with the device contacts 106. Accordingly, facile access to device contacts 106 may be provided through the window 210.

An alignment mechanism may be provided for aligning the elements of the invention, e.g., the substrate, the microelectronic device, etc. In general, aligning mechanisms or apparatuses known in the art, e.g., mating features, clips, clamps, guides (mechanical, optical, electronic, or magnetic), devices used in metrology, etc., may be used to facilitate proper positioning of the elements of the invention. Optionally, a locking mechanism may be used as well. The locking mechanism may be the same as or different from the aligning mechanism.

For example, to maintain the relative positions of the device contacts 106 relative to the window, an adhesive 220 may be used to bond the device 100 to the substrate 200. As shown in FIG. 1, the adhesive 220 is provided between the front device surface 102 and the first substrate surface 202. Any of a number of adhesives known in the art may be used. For example, a curable liquid may be placed between the device 100 and the substrate 200 and subjected curing conditions to form an adhesive polymer layer therebetween. Additional adhesives, e.g., pressure-sensitive adhesives or solvent containing adhesive solutions may be used as well.

A plurality of terminals 300 is provided on the second substrate surface 204. Electrically conductive regions 302 in the form of wiring traces may be provided in electrical communication with the terminals. The terminals and the wire traces may be comprised of one or more electrically conductive material. They may be formed form the same or different materials.

Typically, the conductive surface regions are made from one or more metals. For example, a conductive region may be comprised of solid copper or a composite composition containing copper particles. Additional metals suitable for use in the invention include, for example, gold, silver, nickel, tin, chromium, iron, aluminum, zinc, titanium, platinum, combinations thereof, and alloys of any of the foregoing such as brass, bronze, and steel. In some instances, a surface layer may be provided over a base conductive layer of the electrically conductive regions, wherein the surface and base layers have differing compositions. For example, a highly conductive coating such as gold, gold/nickel, gold/osmium or gold/palladium, may be coated on a less conductive material. In addition or in the alternative, a base layer may be plated with a wear resistant coating such as osmium, chromium or titanium nitride.

It should be noted that the substrate 200 and the terminals 300 may be provided as an unitary item. That is, the substrate may be complete with conductive regions 302 in the form wire traces in contact with the terminals 300 before bonding to the microelectronic device. Solder 304 and solder resist 306 may be placed on the second substrate surface as well. Alternatively, the terminals 300, conductive regions 302, and/or solder 304 may be placed on the substrate after the substrate is bonded to the device 100.

Solder suitable for use with the invention may take any of a number of forms. Typically, balls or spheres are used. Pastes and other forms of solder may used as well. Regardless of the form of solder used, any various fusible alloys may be used. For example, eutectic solders containing tin and/or lead are known in the art. Optionally, a flux may be present in the solder or on the surfaces to be joined so as to promote wetting and bonding of metallic parts.

When solder is used to provide connections between the packaged device and an external circuit such as a printed circuit board (PCB), it is desirable to prevent uncontrolled wicking, wetting and other forms of uncontrolled solder flow. Thus, a solder resist, typically an organic material, may be used to mask areas adjacent to the regions on which the solder may contact. In particular, a solder resist may serve to prevent lateral flow of the solder along the wiring trace.

The terminals and the wire traces may be formed on the second substrate surface using a number of well known additive or subtractive processes. An example of an additive process involves coating the second substrate surface with photoresist, exposing a negative pattern, developing the pattern to leave photo resist in surface areas where no trace is required and then blanket coating. Once the remaining photoresist is removed from the substrate surface, only the desired terminals and wiring traces remain.

As shown in FIG. 1, wires 310 may serve to provide electrical communication between the device contacts 106 and the terminals 300 via traces 302. In general, the wires may be made from any material used to form the conductive regions. To promote low inductance and capacitance, however, it is preferred that the wires be short. As shown, wires 310 are formed such that they do not protrude beyond the plane defined by the surface of the solder balls opposing the surfaces in contact with the terminals.

Notably, wire, lead, or other flexible bonding techniques allow relative movement between contacts of the device and the terminals of the package. As discussed in detail below, thermal cycling of CTE mismatched items may cause rigid bonds that serve as electrical connection between the items to undergo fatigue. A flexible bond may allow for relative movability between the items, e.g., device contacts and terminals, so as to provide substantial fatigue relief undergoing thermal cycling.

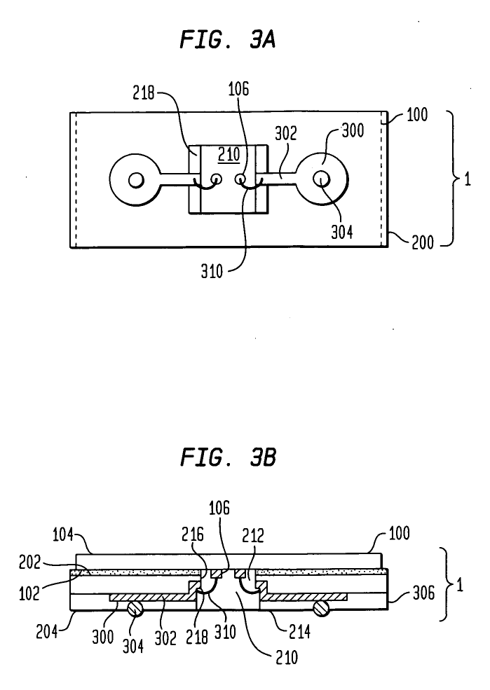

Alternatively, the window in the substrate may have a different geometry and/or shape. FIG. 3 schematically illustrate an exemplary package similar to that depicted in FIG. 1 in that a microelectronic device 100 is provided having opposing front and rear major surfaces indicated at 102 and 104, respectively and a plurality of electrical contacts 106 on the front surface 102. However, there are a number of notable differences between the substrate of FIG. 1 and the substrate of FIG. 3. As an initial matter, the substrate 200 of FIG. 3 is depicted having a footprint that is larger than of the device 100. In addition, unlike the substrate depicted in FIG. 1, the first opening 212 of window 210 has a smaller cross-sectional area than that of the second opening 214. The cross-sectional area of the larger opening may range from twice as large to many times larger than that of the smaller opening. Accordingly, as the window 210 extends between the first and second openings 212, 214, the window 210 has varied cross-sectional areas along its lumen as defined by its side wall 216.

Furthermore, a side wall ledge 218 is included. As shown, the ledge 218 has a surface that is substantially planar and parallel to the second substrate surface 204. Thus, the side wall 216 are depicted as extending perpendicularly away from the first substrate surface 202 until they reach the ledge 218. The ledge extends parallel to the second substrate surface 204 and turn abruptly and perpendicularly toward the second substrate surface 204. In the alternative (not shown) the ledge may turn gradually and/or slopingly toward the second substrate surface. As discussed herein, gradual and/or sloping profiles render the profile easier to metallize.

In any case, electrically conductive regions 302 are provided on ledge 218. The conductive regions extend along the side wall 216 and the second substrate surface 204 until they terminate at terminals 300. Wires 310 are attached to device contacts 106 and conductive regions 302 on ledge 218.

Optionally, as shown in FIG. 3, an encapsulant 400 may be used to protect the connections established in the window 210 as well as the front device surface 102. For full protection, chemical, mechanical, or otherwise, the encapsulant 400 may fill the window to a substantially void-free degree. However, the encapsulant 400 may not in some instances extend to a significant degree past the second substrate surface 204.

Any of a number of encapsulants may be used. For example, polymeric encapsulants may be chosen to include or exclude any group or moiety according to the intended function of the coating. In some instances, the coating may contain cyclic and/or aromatic groups. Exemplary polymers containing cyclic moieties include polycarbonate, polyimide, and polystyrene. Other suitable polymers include, but are not limited to, polyesters such as polyethylene terephthalate and polyethylene naphthalate, polyalkanes such as polyethylene, polypropylene and polybutylene, halogenated polymers such as partially and fully fluorinated polyalkanes and partially and fully chlorinated polyalkanes, polycarbonate, epoxies, polysiloxanes, combinations thereof, and copolymers of any of the foregoing. Optionally, nonpolymeric materials may be included as a component of the encapsulant. In any case, the encapsulant should not interfere with proper functioning of the elements in the window. For example, if wires in the window are required to be movable, the encapsulant should not impede movement of the wires to a substantial degree.

Thus, the presence of the ledge provides a number of advantages over a side wall that does not have a ledge such as that depicted in FIG. 1. As an initial matter, the ledge allows for wire or lead bonding to be carried out such that the wire or lead bond does not extend past the second substrate surface. In addition, the ledge is easily accessible through the second window opening for wire or lead bonding between the device contacts and the conductive regions. In summary, the ledge allows the device contacts to be electrically connected to the terminals using wire or lead bonding techniques which do not result with wires or leads extending past the second substrate surface.

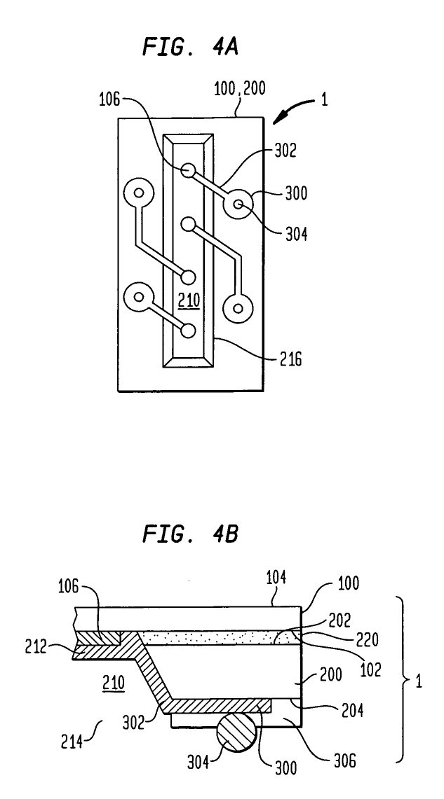

As a further alternative, FIG. 4 depicts an exemplary package whose substrate window has differs in shape and geometry from those depicted in FIGS. 1 and 3. In general, the package depicted in FIG. 4 is similar to that of FIG. 3 in that they both include a device 100 and a substrate 200. In addition, both windows 210 have first openings 212 having greater cross-sectional areas than the respective second openings 214. However, the window 210 of FIG. 4 has no side wall ledge 218. Instead, the side wall 216 of the window extends slopingly from the first opening 212 to the second opening. The conductive regions 302 lie along the side wall 216 and the second substrate surface 204 until they terminate at terminals 300. As shown, the conductive regions 302 may be formed such that they extend over the device contacts 106, thereby providing electrical communication between the device contacts 106 and the terminals 300. Alternatively, a wire, lead or other conductive item (not shown) may be positioned such that it contacts the device contacts 106 and the conductive regions 302 on the side wall 216 of the window 210 so as to establish electrical communication between the device contacts 106 and the terminals 300.

Thus, it should be apparent that a substrate window having a sloping side wall generally provides generally the same advantages as a substrate window having a ledge. However, such a sloping wall geometry provides a further advantage when viewed in context that is not an easy task to form windows having ledges and substantially perpendicular walls in ceramics materials. When a tapered window is provided, it may be advantageous to apply the conductive region, e.g., wiring trace, to the window side wall after the substrate has been attached to the device. As a result, a continuous conductive pathway may be formed from the device contact to the terminal on the second substrate surface.

For example, the terminal and the conductive region are comprised of a contiguous coating of substantially uniform composition. Such a coating may be a vapor-deposited metal (e.g., sputtered, evaporated, etc.). While less than manufacturing-friendly deposition times may be needed to produce vapor-deposited films having a thickness greater than about 5 micrometers, vapor deposited films having thicknesses of no greater than about 3 micrometers are known in the art. Optimally, the thickness of the contiguous coating may be about 0.1 to about 1 micrometer.

Thus, variations on the window and side wall geometries and/or shapes may be advantageously used as well. Exemplary tapered profiles may correspond to polyhedrons such as tetrahedrons, cones, and pyramids. One of ordinary skill in the art will recognize that many suitable window geometries exhibit axial or mirror symmetry.

Taper angles may be selected according to the requirements for forming the contiguous coating as well as the requirements of the package. For example, a shallow angle tends to allow the thickness of conductive coating on the side wall to increase at nearly the same rate as the thickness of the conductive coating on the second substrate surface. However, a shallow angle requires more substrate area. Thus, a taper angle of about 5° to about 60° is typically used. In some instances, taper angle of about 20° to about 60° may be employed. A taper angle of 45° may be optimal for many applications.

Less commonly, window may have side wall profiles that include a narrow region between the openings thereof. The narrow region may have a smaller cross-sectional area than either the openings. In any case, when a substrate contains a plurality of windows, they may have the same shape and/or size. However, windows of different sizes and shapes may be used as well.

A number of techniques may be employed to reduce the profile of the package. For example, terminal height, solder ball size, and/or substrate thickness may be reduced. Alternatively, substrate geometry may be altered to reduce the profile of the package.

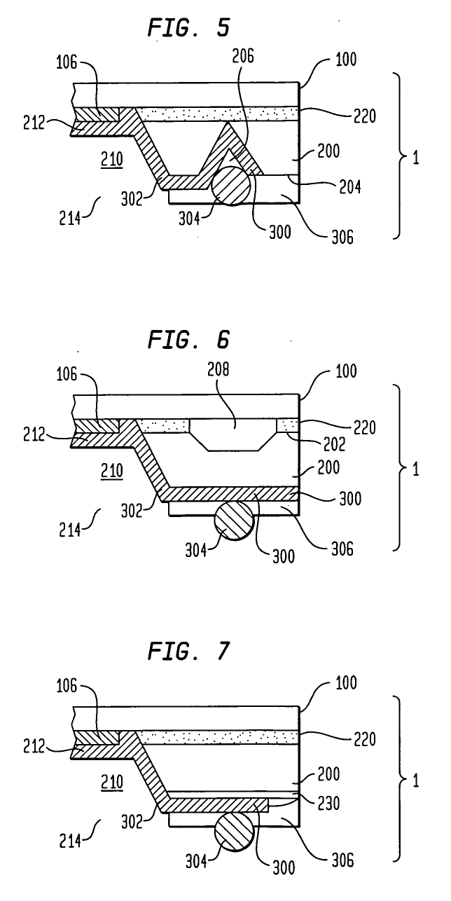

FIG. 5 schematically illustrates in cross-sectional view an interconnect structure of a package that has a reduced profile. In general, FIG. 5 depicts an exemplary package whose substrate window has the same shape and geometry from that depicted in FIG. 4. However, a blind tapered recess 206 is provided in the second substrate surface 204 containing terminal 300. The tapered profile of the recess 206 facilitates deposition of a contiguous conductive coating that serves as a conductive pathway 302 and the terminal 300. By locating solder 304 in the blind recess 206, the stand off height of the device can be decreased relative to any PCB bonded to the solder 304.

As discussed above, the front device surface is typically placed in facing relationship to the first substrate surface. In addition, as depicted in FIGS. 1 and 3-5, the surfaces may be bonded to each other through the use of an adhesive. However, the surfaces may also be placed in direct contact with each other. In any case, there is typically substantially no void between the first substrate surface and the front device surface. However, void-free spatial relationship between the surfaces is not a requirement for the invention.

For example, FIG. 6 schematically illustrates in cross-sectional view an interconnect structure for a package that includes a substrate window having the same shape and geometry from that depicted in FIGS. 4 and 5. Unlike the above-described substrates, however, the first substrate surface 202 contains a recess 208. In some instances, the substrate may be cast, sintered, or otherwise processed such that the recess 208 is formed with the substrate. In addition or in the alternative, the recess may be formed through removing material from the substrate surface to a controlled depth and area using techniques in the art, including, but not limited to chemical etching, mechanical grinding, laser ablation, and combinations thereof. As are result, a local cavity is provided. Cavity packages are particularly suited for applications involving moving parts, such as MEM as well as image sensors, digital light projectors, radio frequency devices (e.g., amplifiers and surface acoustic wave devices).

Any of the packages described herein may be formed using a wafer-scale process or method. In general, a unitary wafer is provided comprising a plurality of microelectronic devices. Typically, the devices are arranged in an array and have coplanar front surfaces with a plurality of electrical contacts thereon. Also provided is a unitary ceramic substrate having a first substantially planar surface and a second surface opposing first surface. One or more windows each having varied cross-sectional areas extend from a first opening on the first surface along a side wall to a second opening on the second surface. The wafer and the substrate are arranged such that the first surface of the substrate faces the front device surfaces, and each first opening is aligned with at least one electrical contact on a different device. The device contacts are provided electrical communication with conductive regions and or terminals on the second substrate through the one or more windows. Once completed, the assembly may be diced to form individual microelectronic packages.

As alluded to above, CTE mismatch between items requiring electrical communication is a source of significant concern for microelectronic packages and assemblies. Problems associated with CTE mismatch between the device and the substrate tend to become exacerbated with an increase in device size. Similarly, in a wafer-scale packaging context, CTE mismatch is significantly more problematic when compared CTE mismatch for packages formed from individual devices. Thus, for wafer-scale assemblies, the substrate and the wafer should have closely matched CTE. In general, the substrate and the wafer may have a CTE mismatch of no more than about 1 ppm/°C. As the size of the wafer increases, the CTE of the wafer and the substrate should be more closely matched. For example, when the wafer has a diameter of at least 200 mm, the substrate and the wafer may have CTE that differ by no more than about 0.2 ppm/°C. Optimally, the CTE for the wafer and the substrate differ by no more than about 0.1 ppm/°C. For wafers having a diameter less than 200 mm, CTE differences of about 0.3 ppm°C. may be acceptable. Ceramics having a CTE close to that of silicon is known in the art. Glasses having a CTE close to that of silicon are available from Corning Incorporated (Corning, N.Y.) and Schott North America, Inc. (Elmsford, N.Y.).

Differences between CTE of the substrate and an external circuit, e.g., on a PCB, may cause the terminals of the package and the circuit to be displaced to a different degree under thermal cycling conditions. Thus, when the terminals are rigidly bonded to the PCB to establish electrical communication therebetween, it is preferred that the materials of the PCB be selected such that the PCT has a similar or identical CTE to that of the device so that stress and fatigue imposed on the bonds, e.g., due to thermal cycling, are minimized. Otherwise, stresses and strain between the package and the PCB have to be absorbed by the bonds.

The life of the bonds can be predicted using numerical modeling techniques. From a simplistic perspective, the fatigue life of the bonds depends on the magnitude of the thermal expansion mismatch, the range of the thermal excursion the package experiences after being attached to the circuit and the material of the bond. Some solders are superior to others. Likewise, solder balls with polymer collars and solder balls having solid metal or polymer cores usually confer extended fatigue life. In addition or in the alternative, the solder of a certain minimum dimension may be used to accommodate the thermal expansion mismatch between the package and the external circuit with sufficient reliability. The package in FIG. 5 is particularly suited for use with such solder to reduce overall package height.

Alternatively, terminals of the package may be bonded to the external circuit in a manner that allows for movement between the terminals and the circuit. This may involve using wire or lead bonds.

In some instances, the inventive packages and assemblies may include a compliant material to provide substantial fatigue relief. For example, FIG. 7 schematically illustrates in cross-sectional view an interconnect structure for an exemplary package that includes a compliant layer. In general, the package 1 is similar to that depicted in FIG. 4 in that they both include a device 100 and a substrate 200 having a window 210 with a first opening 212 having greater cross-sectional areas than a second opening 214. However, a compliant layer 230 is provided between the device and at least one terminal. In particular, the layer 230 is depicted is located between the terminal 300 and the substrate 200. The compliant layer 230 may be continuous over the entire second substrate surface 204 or simply at the discrete locations corresponding to the location of the terminals 300. As a result, the terminal 300 is decoupled from the substrate 200 and the device 100.

Exemplary materials suitable for forming the compliant layer include elastomers, foams, gels or other materials commonly regarded as being “soft” over a wide range of temperatures. In addition, materials such as thermoplastics or thermosetting polymers having elastic modulus which decreases substantially at temperatures which may be above room temperature but within the ranges encountered in service or under extreme thermal conditions which may be imposed by the environment. For example, compliant materials used may undergo a substantial reduction in elastic modulus and/or shear modulus at temperatures on the order of 100° C. Polyimide and other polymers known in the art may serve as a compliant layer material.

It should be noted that the term “substantial” as used to describe the term “fatigue relief,” refers, among other things, to the increase in the average number of cycles for an electrical path to failure by at least two-fold as compared to the cycles for an electrical path that undergoes fatigue without substantial fatigue relief. Preferably, the average number of cycle to failure is increased by ten-fold. The terms “substantial” and “substantially” are used analogously in other contexts involve an analogous definition. Optionally, a compliant layer may be provided between the device and the substrate.

Thus, the invention provides previously unknown advantages in the art of microelectronic packaging. In general, the ceramic substrate has comparable performance to polyimide tape substrate but is less costly. In addition, certain processes associated with the inventive packages may be performed during wafer fabrication, e.g., sputtering and window etching. Furthermore, the inventive packages and assemblies provide a reduced total package profile and/or height. The package is associated with high productivity and fast turn around due to its simplicity.

Variations of the present invention will be apparent to those of ordinary skill in the art in view of the disclosure contained herein. For example, while the unitary substrates have generally been depicted herein as formed from a single piece, a plurality of pieces may be joined to form a unitary substrate may be used as well. In addition, solders, conductive pastes, and other electrical connection technologies known in the art may be employed to effect electrical communication between any items of the invention. Furthermore, the inventive packages and assemblies may serve to provide mechanical support to the packaged device or wafer to facilitate their back-grinding. Additional variations of the invention may be discovered upon routine experimentation without departing from the spirit of the present invention.

Although the invention herein has been described with reference to particular embodiments, it is to be understood that these embodiments are merely illustrative of the principles and applications of the present invention. It is, therefore, to be understood that numerous modifications may be made to the illustrative embodiments and that other arrangements may be devised without departing from the spirit and scope of the present invention as defined by the appended claims.

All patents and patent applications mentioned herein are hereby incorporated by reference in their entireties.

1. A microelectronic package, comprising:
a microelectronic device having a substantially planar front surface and a plurality of electrical contacts thereon;
a unitary ceramic substrate having
a first substantially planar surface,
a second surface opposing first surface,
a window having varied cross-sectional areas and extending from a first opening on the first surface along a side wall to a second opening on the second surface, and
a conductive region on the side wall; and
a plurality of terminals,
wherein the substrate is located between the device and the terminals such that the first surface of the substrate faces the front surface of the device and the first opening is aligned with the contacts on the front device surface.

2. The package of claim 1, wherein the device is a memory chip.

3. The package of claim 1, wherein the electrical contacts are located in a central portion of the front device surface.

4. The package of claim 1, wherein the electrical contacts are substantially absent from a peripheral portion of the front device surface.

5. The package of claim 1, wherein the first opening has a smaller cross-sectional area than the second opening.

6. The package of claim 5, wherein the side wall is tapered from the second opening to the first opening.

7. The package of claim 1, wherein the side wall includes a ledge.

8. The package of claim 7, wherein the conductive region is present on the ledge.

9. The package of claim 1, having substantially no void between the first surface of the substrate and the front surface of the device.

10. The package of claim 1, further comprising an adhesive between the device and the substrate.

11. The package of claim 1, further comprising a compliant layer between the device and at least one terminal.

12. The package of claim 11, wherein the compliant layer is located between the at least one terminal and the substrate.

13. The package of claim 11, wherein the compliant layer is located between the device and the substrate.

14. The package of claim 1, wherein at least one device contact is in electrical communication with at least one terminal through the window via the conductive region.

15. The package of claim 14, wherein the at least one device contact is lead bonded or wire bonded to the conductive region.

16. The package of claim 1, comprising different conductive regions on different portions of the side wall, wherein different device contacts are in electrical communication with different terminals through the window via different conductive regions.

17. The package of claim 14, further comprising an encapsulant within the window.

18. The package of claim 17, wherein encapsulant fills the window to a substantially void-free degree.

19. The package of claim 1, wherein the substrate is comprised of an amorphous ceramic material.

20. The package of claim 1, further comprising a recess on the second substrate surface that contains at least one terminal.

21. The package of claim 1, wherein the terminal and the conductive region are comprised of a contiguous coating of substantially uniform composition.

22. The package of claim 21, wherein the contiguous coating is comprised of a metal.

23. The package of claim 21, wherein the contiguous coating has a thickness no greater than about 5 micrometers.

24. The package of claim 23, wherein the thickness of the contiguous coating is no greater than about 3 micrometers.

25. The package of claim 24, wherein the thickness of the contiguous coating is about 0.1 to about 1 micrometer.

26. The package of claim 1, further comprising solder balls and solder resist on the second surface of the substrate.

27. A microelectronic package, comprising:
a microelectronic device having a substantially planar front surface and a plurality of electrical contacts thereon;
a unitary ceramic substrate having
a first substantially planar surface,
a second surface opposing first surface,
a window extending from a first opening on the first surface along a side wall to a second opening on the second surface, and
a metal coating on the side wall and/or the second substrate surface; and
+P2
a plurality of terminals,
wherein the substrate is located between the device and the terminals such that the first surface of the substrate faces the front surface of the device, the first opening is aligned with at least one contact on the front device surface, and the at least one device contact is in electrical communication with at least one terminal through the window via a lead or wire bond to the conductive region.

28. A wafer-scale microelectronic assembly, comprising:
a wafer comprising an array of microelectronic devices each having a coplanar front surface and a plurality of electrical contacts thereon; and
a unitary ceramic substrate having
a first substantially planar surface
a second surface opposing first surface,
a plurality of windows each having varied cross-sectional areas extending from a first opening on the first surface along a side wall to a second opening on the second surface, and
a conductive region on at least a portion of each side wall,
wherein the first surface of the substrate faces the front device surfaces, and each first opening is aligned with electrical contacts on a different device.

29. A wafer-scale microelectronic assembly, comprising:
a wafer comprising an array of microelectronic devices each having a coplanar front surface and a plurality of electrical contacts thereon; and
a unitary ceramic substrate having
a first substantially planar surface
a second surface opposing first surface,
a window having varied cross-sectional areas extending from a first opening on the first surface along a side wall to a second opening on the second surface, and
a conductive region on each side wall,
wherein the first surface of the substrate faces the front surface of the device, and the first opening is aligned with at least one electrical contact on each different device.

30. A wafer-scale microelectronic assembly, comprising:
a wafer having a diameter of at least 200 mm comprising an array of microelectronic devices each having a coplanar front surface and a plurality of electrical contacts thereon; and
a unitary ceramic substrate having
a first substantially planar surface
a second surface opposing first surface, and
a window having varied cross-sectional areas extending from a first opening on the first surface along a side wall to a second opening on the second surface,
wherein the substrate is positioned such that the first surface of the substrate faces the front surface of the device, each first opening is aligned with at least one electrical contact on different device, and the substrate and the device have coefficients of thermal expansion that differs by no more than about 0.1 ppm/°C.

31. A method for forming a microelectronic package, comprising:
(a) providing
a microelectronic device having a substantially planar front surface and a plurality of electrical contacts thereon, and
a unitary ceramic substrate having a first substantially planar surface, a second surface opposing first surface, a window having varied cross-sectional areas and extending from a first opening on the first surface along a side wall to a second opening on the second surface, and a conductive region on the side wall,
wherein the first surface of the substrate faces the front surface of the device and the first opening is aligned with at least one contact on the front device surface; and
(b) establishing electrical communication between at least one contact and the conductive region through the first opening.

32. The method of claim 31, wherein step (b) comprises lead bonding or wire bonding at least one device contact to the conductive region.

33. The method of claim 31, further comprising step (c) providing a terminal that electrically communicates with the electrically conductive region.

34. The method of claim 33, wherein step (c) is carried out before step (b).

35. The method of claim 33, further comprising, during or after step (b), filling the window with an encapsulant.

36. The method of claim 33, further comprising step (d) establishing electrical communication between the terminal and an external circuit.

37. The method of claim 36, wherein step (b) comprises soldering, lead bonding or wire bonding the terminal to the external circuit.

38. A method for forming a microelectronic assembly, comprising:
(a) providing
a wafer comprising an array of microelectronic device each having a coplanar front surface and a plurality of electrical contacts thereon, and
a unitary ceramic substrate having a first substantially planar surface, a second surface opposing first surface, an array of windows each corresponding to a different microelectronic device, having varied cross-sectional areas, and extending from a first opening on the first surface along a side wall to a second opening on the second surface, and a conductive region on each side wall,
wherein the first surface of the substrate faces the front surfaces of the devices and each first opening is aligned with contacts on the front surface of the corresponding microelectronic device; and
(b) establishing electrical communication between at least one contact for each device and the conductive region on the side wall of the window corresponding to each device, thereby forming a microelectronic assembly.

39. The method of claim 38, further comprising dicing the microelectronic assembly into individual microelectronic packages.
